(19) United States
(12) Patent Application Publication
(10) Pub. No.: US 2015/0122532 A1
(43) Pub. Date: May 7, 2015

(54) HIGH TEMPERATURE MULTILAYER FLEXIBLE PRINTED WIRING BOARD

(71) Applicant: Teledyne Technologies Incorporated, Thousand Oaks, CA (US)

(72) Inventors: Robert A. Nelson, Hudson, NH (US); Raymond L. Dubois, Wilmington, MA (US); Michael A. Collier, Bedford, NH (US); James E. Keating, Milford, NH (US)

(21) Appl. No.: 14/527,124

(22) Filed: Oct. 29, 2014

Related U.S. Application Data
(60) Provisional application No. 61/899,628, filed on Nov. 4, 2013.

(51) Int. Cl. H05K 1/03; H05K 1/02

(52) U.S. Cl. CPC H05K 1/0366; H05K 1/028; H05K 1/0393; H05K 2201/0154; H05K 2201/0293
USPC 174/254

(57) ABSTRACT

In various embodiments, high temperature printed circuit boards are disclosed. In one embodiment, a high temperature printed circuit board (PCB) comprises a first reinforced pre-impregnated layer and a second reinforced pre-impregnated layer. The first reinforced pre-impregnated layer and the second reinforced pre-impregnated layer comprise a plurality of glass fibers having a warp and a weft and impregnated with a polyimide high-temperature resin adhesive. A flexible metal-clad polyimide laminate material is located between the first reinforced pre-impregnated layer and the reinforced second pre-impregnated layer. The flexible metal-clad polyimide laminate material comprises a plurality of conductive traces. A polyimide film is disposed over the first pre-impregnated layer and the second pre-impregnated layer.

### CROSS-REFERENCE TO RELATED APPLICATION

This application claims the benefit of U.S. Provisional Pat. Appl. No. 61/899,628, filed on Nov. 4, 2013, entitled HIGH TEMPERATURE MULTILAYER FLEXIBLE PRINTED WIRING BOARD, the disclosure of which is hereby incorporated by reference in its entirety.

### BACKGROUND

The present disclosure is related generally to high temperature printed wiring boards. More particularly, the present disclosure is related to high temperature multilayer printed wiring boards. Still more particularly the present disclosure is related to high temperature multilayer flexible printed wiring boards.

Flexible circuits comprise electronic circuits assembled by mounting electronic devices on flexible plastic substrates with a conductor on one or both sides of the plastic substrate. The flexible printed circuits are made with a photolithographic technology. After removal of the excess copper, leaving copper conductors behind on the plastic laminate, the copper conductors are covered with a layer of substrate and laminated using a thermosetting acrylic adhesive. Despite these advances in flexible circuit technology, these materials are only useable up to about 110° C. and are not capable of continuous use high temperatures in harsh environment applications and are not capable of performing at elevated temperatures for extended periods of time. Currently, there is no solution available to industry, such as the oil and gas industry, for a rigid flexible circuit to function at elevated temperatures with high reliability. Other components such as connectors and other electronics have been developed to withstand this environment but no printed circuit board (PCB) design has been presented.

### SUMMARY

In various embodiments, high temperature printed circuit boards are disclosed. In one embodiment, a high temperature printed circuit board (PCB) comprises a first reinforced pre-impregnated layer and a second reinforced pre-impregnated layer. The first reinforced pre-impregnated layer and the second reinforced pre-impregnated layer comprise a plurality of glass fibers having a warp and a weft and impregnated with a polyimide high-temperature resin adhesive. A flexible metal-clad polyimide laminate material is located between the first reinforced pre-impregnated layer and the reinforced second pre-impregnated layer. The flexible metal-clad polyimide laminate material comprises a plurality of conductive traces. A polyimide film is disposed over the first pre-impregnated layer and the second pre-impregnated layer.

In one embodiment, a flexible circuit capable of continuous use at a temperature of at least about 260° C. is disclosed. The flexible circuit comprises a first pre-impregnated layer and a second pre-impregnated layer. The first pre-impregnated layer and the second pre-impregnated layer comprise a polyimide pre-impregnated material comprising a plurality of fibers having a warp and a weft and a pre-impregnated high-temperature adhesive. A laminate material is located between the first pre-impregnated layer and the second pre-impregnated layer. The laminate material comprises a plurality of conductive traces. A polyimide film is disposed over the first pre-impregnated layer and the second pre-impregnated layer.

The foregoing is a summary and thus may contain simplifications, generalizations, inclusions, and/or omissions of detail; consequently, those skilled in the art will appreciate that the summary is illustrative only and is NOT intended to be in any way limiting. Other aspects, features, and advantages of the devices and/or processes and/or other subject matter described herein will become apparent in the teachings set forth herein.

### DRAWINGS

The features of the various embodiments are set forth with particularity in the appended claims. The various embodiments, however, both as to organization and methods of operation, together with advantages thereof, may best be understood by reference to the following description, taken in conjunction with the accompanying drawings as follows:

FIG. 1A illustrates one embodiment of a multi-layer stack high-temperature printed circuit board (PCB);

FIG. 1B is an exploded view of four layers of one embodiment of the multi-layer stack high-temperature printed circuit board shown in FIG. 1A;

FIG. 2A illustrates one embodiment of a flexible structure comprising a plurality of fibers impregnated with a polyimide high-temperature resin adhesive and having a polyimide layer bonded thereon;

FIG. 2B illustrates the flexible structure of FIG. 2A in a formed position with a tighter bend radius.

FIG. 3A illustrates one embodiment of a flexible structure comprising a plurality of fibers impregnated with a polyimide high-temperature resin adhesive and having a polyimide layer positioned on one side and an adhesiveless laminate bonded on another side;

FIG. 3B illustrates the flexible structure of FIG. 3A in a formed position with a tighter bend radius.

FIG. 4 illustrates one embodiment of a fiber structure comprising a warp and a weave;

FIG. 5 is a sectional view taken along line A-A of the multi-layer stack high-temperature printed circuit board shown in FIG. 1A;

FIG. 6 is a sectional view of one embodiment of a high-temperature printed circuit board comprising a plurality of layers and an isolated conductive laminate where a circuit layer has been pre-routed to a narrower width prior to lamination;

FIG. 7 illustrates one embodiment of a fiber structure having a warp parallel to a plurality of circuits;

FIG. 8 illustrates one embodiment of a fiber structure having a warp diagonal to a plurality of circuits;

FIG. 9 illustrates one embodiment of a fiber structure having a warp perpendicular to a plurality of circuits.

### DESCRIPTION

Before explaining the various embodiments of the high temperature printed circuit boards in detail, it should be noted that the various embodiments disclosed herein are not limited in their application or use to the details of construction and arrangement of parts illustrated in the accompanying drawings and description. Rather, the disclosed embodiments may be positioned or incorporated in other embodiments, variations and modifications thereof, and may be practiced or carried out in various ways. Accordingly, embodiments of the high temperature printed circuit boards disclosed herein are illustrative in nature and are not meant to limit the scope or application thereof. Furthermore, unless otherwise indicated, the terms and expressions employed herein have been chosen for the purpose of describing the embodiments for the convenience of the reader and are not to limit the scope thereof. In addition, it should be understood that any one or more of the disclosed embodiments, expressions of embodiments, and/or examples thereof, can be combined with any one or more of the other disclosed embodiments, expressions of embodiments, and/or examples thereof, without limitation.

Also, in the following description, it is to be understood that terms such as front, back, inside, outside, top, bottom and the like are words of convenience and are not to be construed as limiting terms. Terminology used herein is not meant to be limiting insofar as devices described herein, or portions thereof, may be attached or utilized in other orientations.

In one embodiment, the present disclosure provides a printed circuit board (PCB) solution, preferably that incorporates rigid flexible materials, that is capable of operating in harsh environments such as high temperature of 260° C. or higher for long periods of time without degradation of performance attributed to the circuit board or material used to produce the circuit board.

In one embodiment, the present disclosure is directed generally to high temperature printed circuit boards (PCBs). The present disclosure provides a flexible circuit capable of continuous use at or above 260° C. for harsh environment applications and is capable of performing at such elevated temperatures for extended periods of time, making such a high temperature printed wiring board a candidate for down hole drilling (Oil & Gas Exploration) applications.

In one embodiment, a high temperature wiring board according to the present disclosure utilizes commercially available materials in a unique way to produce a multi-layer PCB board that has some of the advantageous of a rigid flexible circuit (“flex circuit”), that is capable of being bent or formed during installation, but also performs well in a harsh environment.

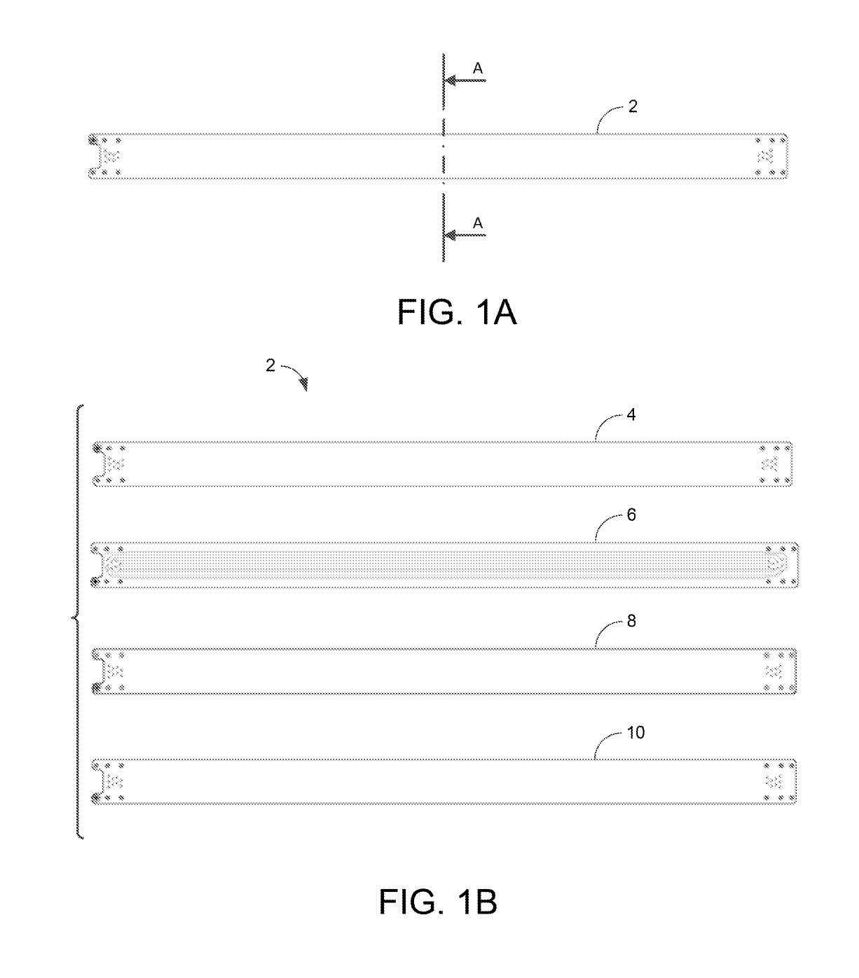

FIG. 1A illustrates one embodiment of a multi-layer stack high-temperature printed circuit board (PCB) 2. The high-temperature PCB 2 is capable of use in harsh environment applications and capable of performing at elevated temperatures, for example, 260° C. or higher, for extended periods of time. The high-temperature PCB 2 comprises a multi-layer PCB board that is capable of being bent or formed during installation and performs well in a harsh environment. The high-temperature PCB 2 comprises a plurality of layers. As shown in FIG. 1B, for example, in one embodiment the multi-layer stack high-temperature PCB 2 may comprise four layers, a top layer 4, a bottom layer 10, and two intermediate layers 6, 8 disposed and laminated between the top and bottom layers 4, 10. Additional or fewer layers may be included depending on the particular implementation.

In one embodiment, a circuit layer is produced using conventional PCB photolithography where an image of conductive traces is transposed to a laminate material consisting of, or comprising, first an insulator clad with a thin sheet of conductive foil on either one or both sides. After the image is transferred, the substrate is processed to first remove the photoresist in select areas so that a portion of the conductive foil is left exposed, and subsequently removed using an etchant solution. This layer is then cleaned and prepared for bonding of an insulating material that will provide environmental sealing as well as electrical insulation. In some embodiments, the circuit layer comprises a high temperature material, such as, for example, a polyimide, as the insulator. For example, in one embodiment, the circuit layer comprises Pyralux® AP 8525 available from E.I. DuPont. For typical applications requiring bending or forming during installation a fabricator would use a polyimide film with an acrylic adhesive as the bond film. One disadvantage of this material is that it does not perform well at high temperature for extended periods of time and this has prohibited the use of this material for certain applications where higher temperatures are encountered during sustained periods of use.

The present disclosure provides a material combination that not only allows the circuits to be bent or formed during installation and use but have utilized materials that are capable of withstanding exposure to harsh environments, such as, for example, elevated temperatures, for extended periods of time without degradation of the material which cause traditional PCB materials to fail. In one embodiment, a high-temperature flexile PCB composite comprises a high temperature pre-impregnated material (a “pre-preg material”) having a fiber or cloth structure that is pre-impregnated with an adhesive resin, such as, for example, a polyimide high temperature thermoplastic polymer as an adhesive and/or bonding material to adhere the pre-impregnated material to the outer surface of the inner-layer circuit. This material is aligned to cover the imaged conductors. A polyimide film is placed over the pre-preg material to encapsulate the material such that the material is supported during flexing and bending.

With reference to FIGS. 1A and 1B, in some embodiments, the layers 4, 6, 8, 10 of the high-temperature flexible PCB 2 are permanently bonded together using traditional PCB laminating conditions and temperature. Several layers 4, 6, 8, 10 are aligned to one another and bonded together using a high temperature adhesive pre-preg material to create a multi-layer substrate capable of being formed in select areas during installation and use that can withstand elevated temperatures for an extended period of time during use. One advantage of the present process for making a high temperature multilayer flexible PCB 2 is that no special processing equipment or procedures are required to create the high-temperature flexible PCB 2.

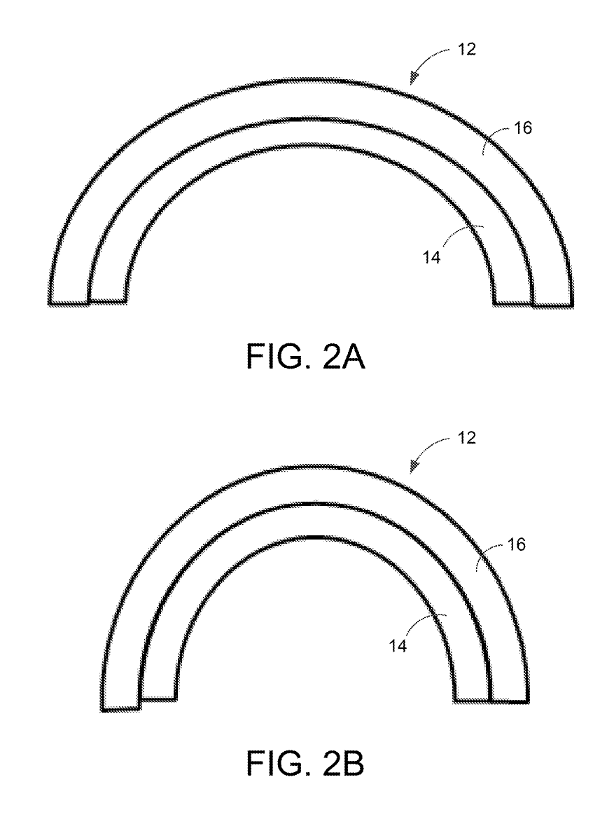

FIGS. 2A and 2B illustrate one embodiment of a suitable material for at least one layer of the high-temperature PCB 2. FIG. 2A illustrates one embodiment of a flexible structure 12 comprising a pre-impregnated material 14 having a plurality of fibers impregnated with a polyimide high-temperature resin adhesive. The plurality of fibers may comprise any suitable material, such as, for example, glass fibers, carbon fibers, aramid fibers, and/or quartz fibers. The plurality of fibers is arranged in a matrix and is pre-impregnated with a high-temperature adhesive, such as, for example, a polyimide high-temperature resin adhesive. A polyimide layer 16 is bonded over the pre-preg material 14. The polyimide layer 16 distributes stress away from the plurality of fibers of the pre-preg material 14 and allows the flexible structure 12 to have a tighter bend radius than the pre-preg material 8 would otherwise have. FIG. 2B illustrates the flexible structure 12 in a flexed position with a bend radius that is tighter than the bend radius of the flexible structure 12 shown in FIG. 2A.

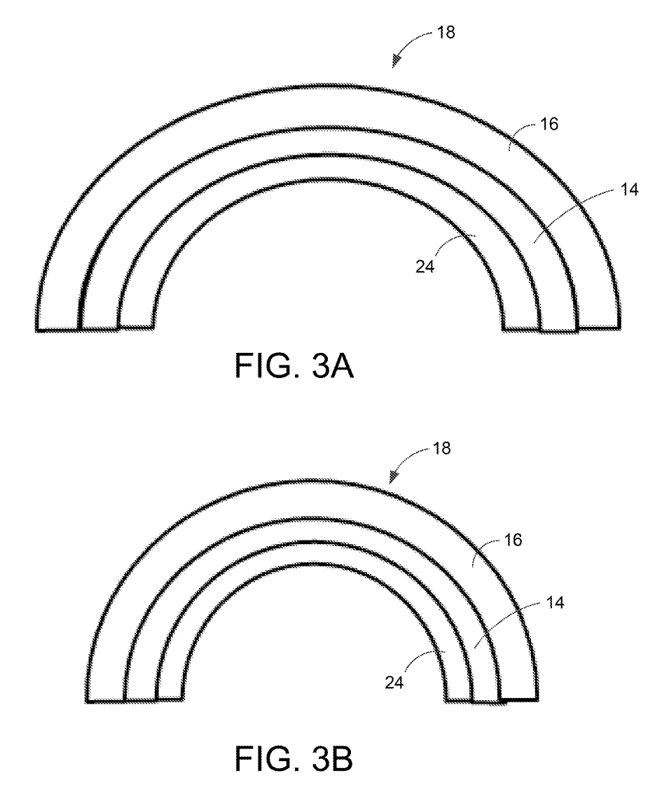

FIGS. 3A and 3B illustrate one embodiment of a suitable material for at least one layer of the high-temperature PCB 2. FIG. 3A illustrates one embodiment of a flexible structure 18 comprising a flexible adhesiveless laminate 24 comprised of at least one conductive layer (copper) and a pre-impregnated material 14 having a plurality of fibers impregnated with a polyimide high-temperature resin adhesive. The plurality of fibers may comprise any suitable material, such as, for example, glass fibers, carbon fibers, aramid fibers, and/or quartz fibers. The plurality of fibers is arranged in a matrix and is pre-impregnated with a high-temperature adhesive, such as, for example, a polyimide high-temperature resin adhesive. A polyimide layer 16 is bonded over the pre-preg material 14. The polyimide layer 16 distributes stress away from the plurality of fibers of the pre-preg material 14 and allows the flexible structure 18 to have a tighter bend radius than the pre-preg material 14 would otherwise have. FIG. 3B illustrates the flexible structure 18 in a flexed position with a bend radius that is tighter than the bend radius of the flexible structure 18 shown in FIG. 3A.

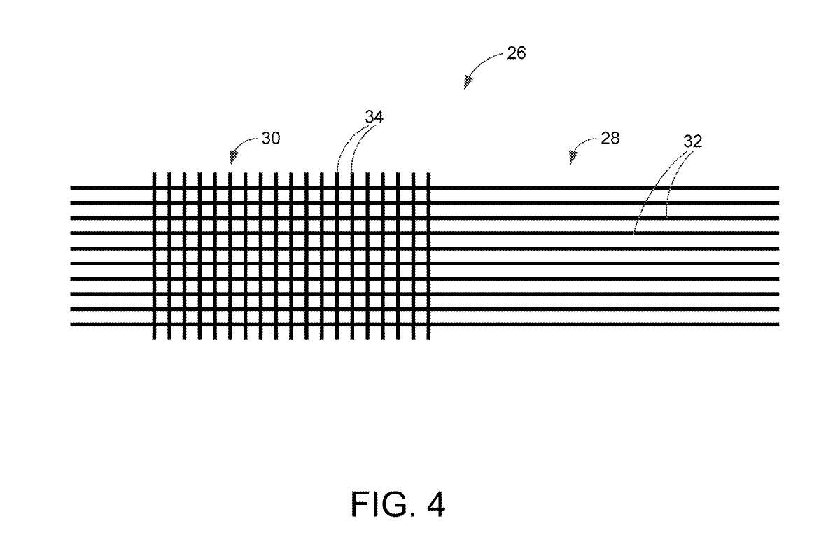

FIG. 4 illustrates one embodiment of a fiber weave 26 comprising a warp 28 and a weft 30. The fiber weave 26 illustrates a fiber weave of, for example, the pre-impregnated material 14 illustrated in FIGS. 2A, 2B and 3A, 3B. The warp 28 comprises a plurality of lengthwise, or longitudinal, fibers 32. The warp 28 comprises long fibers 32 under tension from being pulled during production. The weft 30 comprises a plurality of fibers 34 that are weaved transverse to the lengthwise fibers 32. Unlike the warp 28 fibers 32, the weft 30 fibers 34 are not under tension. The fiber weave 26 is pre-impregnated with a high-temperature adhesive resin, such as, for example, a polyimide high-temperature resin adhesive. The warp 28 comprises a greater number of fibers, or strands, per inch than the weave 34.

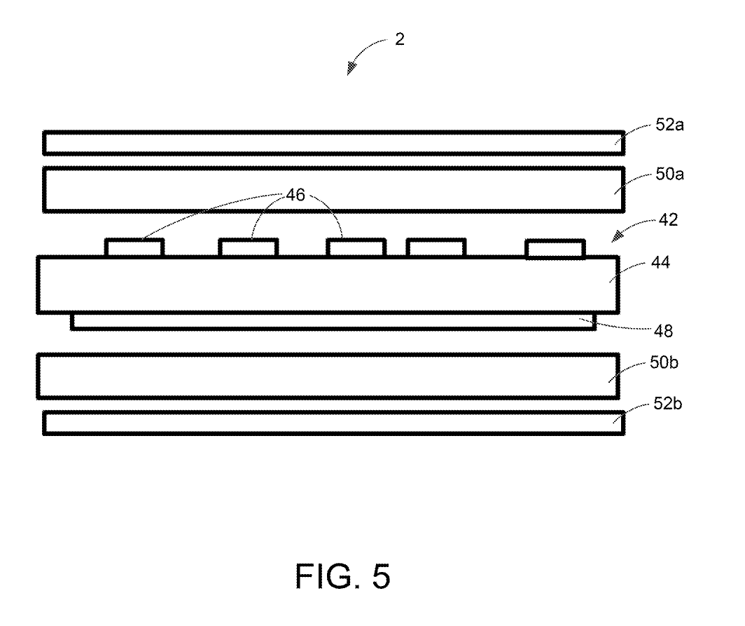

FIG. 5 is a sectional view taken along line A-A of the multi-layer stack high-temperature printed circuit board 2 shown in FIG. 1A. The high-temperature PCB 2 comprises a circuit layer 42. The circuit layer 42 comprises an insulator 44 having a plurality of conductive traces 46 formed on one side. The plurality of conductive traces 46 are formed on one side of the insulator 44 by, for example, PCB photolithography. The plurality of traces 46 may comprise any suitable electrically conductive material. For example, in some embodiments, the plurality of traces 46 comprises a metal material, such as, for example, a copper foil or any suitable electrically conductive material. In one embodiment, the circuit layer 42 comprises a non-reinforced adhesiveless flexible metal-clad polyimide laminate, such as, for example, Pyralux AP (available from EI DuPont). For example, in one embodiment, the circuit layer 42 comprises AP8525 available from EI DuPont comprising 2/1000″ (2 mil) thick Pyralux AP all polyimide composite coated with 2/10000″ to 3/10000″ (0.2 to 0.3 mil) polyimide adhesive and bonded to 7/10000″ (0.7 mil) thick rolled annealed copper on both sides of the composite.

In some embodiments, the circuit layer 42 may comprise any suitable flexible metal-clad polyimide laminate, such as, for example, reinforced, non-reinforced, adhesiveless, and/or pre-impregnated materials. In some embodiments, the circuit layer 42 comprises a liquid crystal polymer material, a cyanide esther material, and/or any other suitable material and a conductive layer. In some embodiments, the circuit layer 42 comprises an electrically conductive layer 48 formed on the other side of the insulator 44. In some embodiments, the conductive layer 48 formed on the other side of the insulator 44 may comprise additional conductive traces or may be comprised of a solid conductive layer that functions as a shield or ground plane.

In the embodiment illustrated in FIG. 5, the circuit layer 42 is located between a first reinforced pre-impregnated layer 50a and a second reinforced pre-impregnated layer 50b. The first and second reinforced pre-impregnated layers 50a, 50b each comprise a fiber weave, as shown in FIG. 4, for example, where the fiber weave is impregnated with a high-temperature resin adhesive. The fiber weave may comprise any suitable material, such as, for example, glass, carbon, aramid, quartz, and/or any other suitable material. The fiber weave is impregnated with a high-temperature resin adhesive comprising, for example, a polyimide high-temperature resin adhesive, a high-temperature thermoset polymers, and/or any other suitable high-temperature resin adhesive. The reinforced pre-impregnated layers 50a, 50b may comprise, for example, a composite material comprising a polyimide component. The polyimide component may comprise a film and/or a resin layer cured during the manufacturing process. For example, in some embodiments, the reinforced pre-impregnated layers 50a, 50b may comprise Isola P25, Isola P26, Isola P95 (each available from Isola USA Corp.), Arlon 33N, Arlon 35N, Arlon 84N, Arlon 85N, Arlon 85NT, Arlon EP2, (each available from Arlon-MED); Nelco N 7000-1, Nelco N-7000-3 (each available from Park Electro-Chemical), and/or any other suitable reinforced pre-impregnated material.

The circuit layer 42, first reinforced pre-impregnated layer 50a, and second reinforced pre-impregnated layer 50b are located between a first polyimide film 52a and a second polyimide film 52b. The polyimide films 52a, 52b distribute stress away from the reinforced pre-impregnated layers 50a, 50b, allowing the high-temperature PCB 2 to flex over a tighter bend radius. The polyimide films 52a, 52b may comprise any suitable polyimide film, such as, for example, reinforced polyimide films and/or non-reinforced polyimide films. In some embodiments the polyimide films 52a, 52b comprise a composite material comprising a polyimide component. For example, in some embodiments, the polyimide films may comprise DuPont AP Products, Kapton Film (such as, for example, Kapton HN, Kapton B, Kapton CR, Kapton FCR, Kapton FN, Kapton FPC, Kapton HPP-ST, Kapton MT, and/or Kapton VN, each available from DuPont USA), and/or any other suitable polyimide film. The circuit layer 42, the reinforced pre-impregnated layers 50a, 50b and the non-reinforced polyimide films 52a, 52b are arranged in a stack as illustrated in FIG. 5 and are bonded using, for example, traditional PCB lamination techniques. The high-temperature printed circuit board 2 is configured to withstand temperatures of up to at least 260° C. and capable of operating in harsh environments.

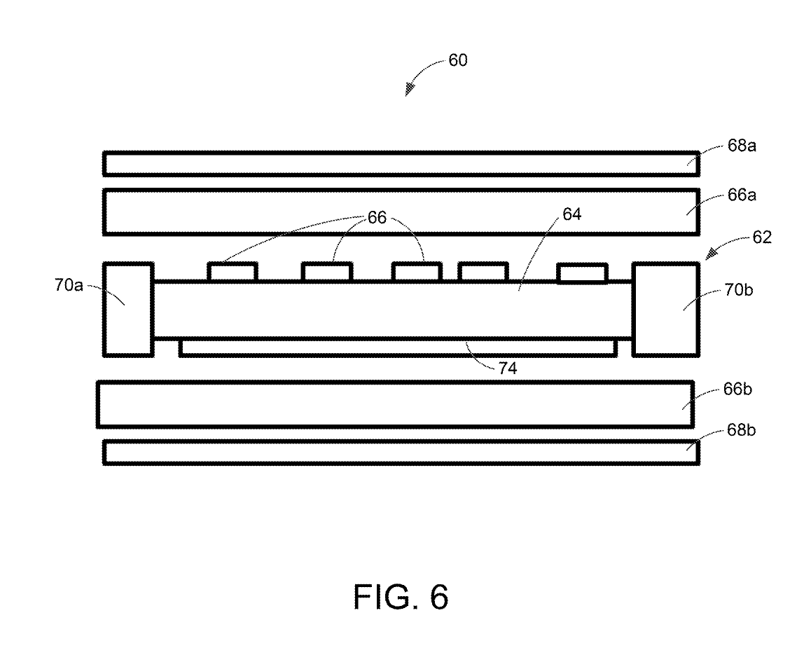

FIG. 6 is a sectional view of one embodiment of a high-temperature printed circuit board 60 comprising a plurality of layers and an isolated conductive laminate where a circuit layer has been pre-routed to a narrower width prior to lamination. The high-temperature PCB 60 comprises a circuit layer 62. The circuit layer 62 comprises an insulator 64 having a plurality of conductive traces 66 formed on the insulator 64. The plurality of conductive traces 66 is formed on the insulator 64 by, for example, PCB photolithography. The plurality of traces 66 may comprise any suitable electrically conductive material. For example, in some embodiments, the plurality of traces 66 comprises a metal material, such as, for example, a copper foil or any suitable electrically conductive material. In one embodiment, the circuit layer 62 comprises a non-reinforced adhesiveless flexible metal-clad polyimide laminate, such as, for example, Pyralux AP (available from EI DuPont). For example, in one embodiment, the circuit layer 62 comprises AP8525 available from EI DuPont comprising 2/1000″ (2 mil) thick Pyralux AP coated with 2/10000″ to 3/10000″ (0.2 to 0.3 mil) polyimide adhesive and a 7/10000″ (0.7 mil) thick rolled annealed copper on both sides of the Pyralux AP material.

In some embodiments, the circuit layer 62 may comprise any suitable flexible metal-clad polyimide laminate, such as, for example, reinforced, non-reinforced, adhesiveless, and/or pre-impregnated materials. In some embodiments, the circuit layer 62 comprises a liquid crystal polymer material, a cyanide esther material, and/or any other suitable material and at least one layer comprising conductive traces 66. In some embodiments, the circuit layer 62 comprises an electrically conductive layer 74 formed on the other side of the insulator 64. In some embodiments, the conductive layer 74 formed on the other side of the insulator 64 may comprise additional conductive traces or may be comprised of a solid conductive layer that functions as a shield or ground plane.

The circuit layer 62 is located between a first reinforced pre-impregnated layer 66a and a second reinforced pre-impregnated layer 66b. The first and second reinforced pre-impregnated layers 66a, 66b each comprise a fiber weave impregnated with a high-temperature resin adhesive. The fiber weave may comprise any suitable material, such as, for example, glass, carbon, aramid, quartz, and/or any other suitable material. The fiber weave is impregnated with a high-temperature resin adhesive comprising, for example, a polyimide high-temperature resin adhesive, a high-temperature thermoset polymer, and/or any other suitable high-temperature resin adhesive. The reinforced pre-impregnated layers 50a, 50b may comprise, for example, Isola P25, Isola P26, Isola P95 (each available from Isola USA Corp.), Arlon 33N, Arlon 35N, Arlon 84N, Arlon 85N, Arlon 85NT, Arlon EP2, (each available from Arlon-MED): Nelco N-7000-1, Nelco N-7000-3 (each available from Park Electro-Chemical), and/or any other suitable reinforced pre-impregnated material.

The circuit layer 62, first reinforced pre-impregnated layer 66a, and second reinforced pre-impregnated layer 66b are located between a first polyimide film 68a and a second polyimide film 68b. The polyimide films 68a, 68b distribute stress away from the reinforced pre-impregnated layers 66a, 66b, allowing the high-temperature PCB 60 to flex over a tighter bend radius. The polyimide films 68a, 68b may comprise any suitable polyimide film, such as, for example, reinforced and/or non-reinforced polyimide films. In some embodiments, the polyimide films 68a, 68b comprise a composite material having a polyimide component. For example, in some embodiments, the polyimide films may comprise DuPont AP Products, Kapton Film (such as, for example, Kapton HN, Kapton B, Kapton CR, Kapton FCR, Kapton FN, Kapton FPC, Katpon HPP-ST, Kapton MT, and/or Kapton VN, each available from DuPont USA), and/or any other suitable polyimide film. The circuit layer 62, the reinforced pre-impregnated layers 66a, 66b and the non-reinforced polyimide films 68a, 68b are arranged in a stack as illustrated in FIG. 6 and are bonded using, for example, traditional PCB lamination techniques. The high-temperature printed circuit board 60 is configured to withstand temperatures of up to at least 260° C.

In some embodiments, the circuit layer 62 is pre-routed to a narrower width prior to lamination of the first and second reinforced pre-impregnated layers 66a, 66b and the polyimide films 68a, 68b. When the circuit layer 62 is pre-routed, the resin adhesive of the first and second reinforced pre-impregnated layers 66a, 66b flows into the slots from the pre-rout and forms side walls 70a, 70b during lamination when temperature and pressure are applied. The final profile of the circuit layer 62 is wider than the previously formed slots in non-pre-routed embodiments, allowing the side walls 70a, 70b to encase the circuit layer 62.

In some embodiments, the circuit layer 62 comprises an electrically conductive layer 74 formed on the other side of the insulator 64. In some embodiments, the conductive layer 74 formed on the other side of the insulator 64 may comprise additional conductive traces or may be comprised of a solid conductive layer that functions as a shield or ground plane.

The illustrated high-temperature flexible PCB boards 2 and 60 comprise a multi-layer stack, as shown for example in FIG. 1B. The multi-layer stack may comprise fewer or additional layers and/or materials than described herein. One example material stack-up is provided in TABLE 1. Those skilled in the art will recognize that the material stack-up of TABLE 1 is provided only as an example and is not intended to be limiting.

TABLE 1

| Material Description | Thickness (Inches) |
|---|---|
| 2 mil KAPTON | 0.002 |
| PP106 C/C | 0.002 |
| ½ oz. copper signals | 0.0007 |
| AP 2 mil Adhesiveless | 0.002 |
| ½ oz. copper shield | 0.0007 |
| PP106 C/C | 0.002 |
| 2 mil KAPTON | 0.002 |

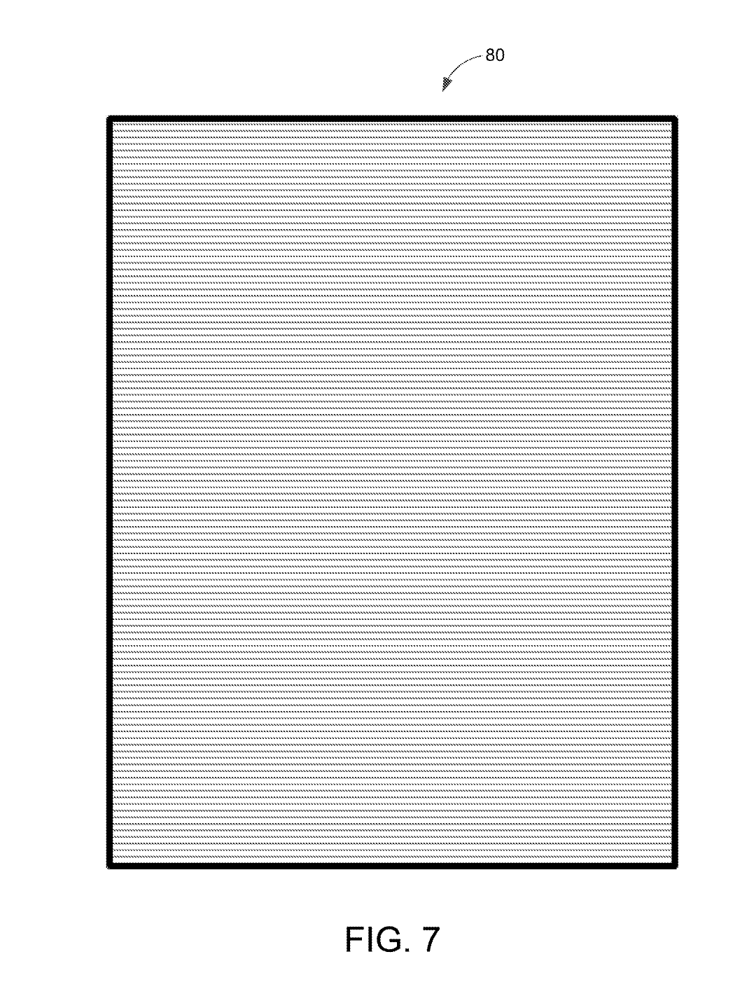

FIGS. 7 to 9 illustrate various embodiments of fiber weaves for reinforced pre-preg layers of the material stack, such as, for example, the pre-preg layers 50a, 50b illustrated in FIG. 5 and the pre-preg layers 66a, 66b illustrated in FIG. 6. FIG. 7 illustrates one embodiment of a fiber weave 80 having a warp parallel to a direction of the conductive traces 46 of the circuit layer 42 shown in FIG. 5. Similarly, the fiber weave 80 has a warp parallel to a direction of the conductive traces 66 of the circuit layer 62 shown in FIG. 6.

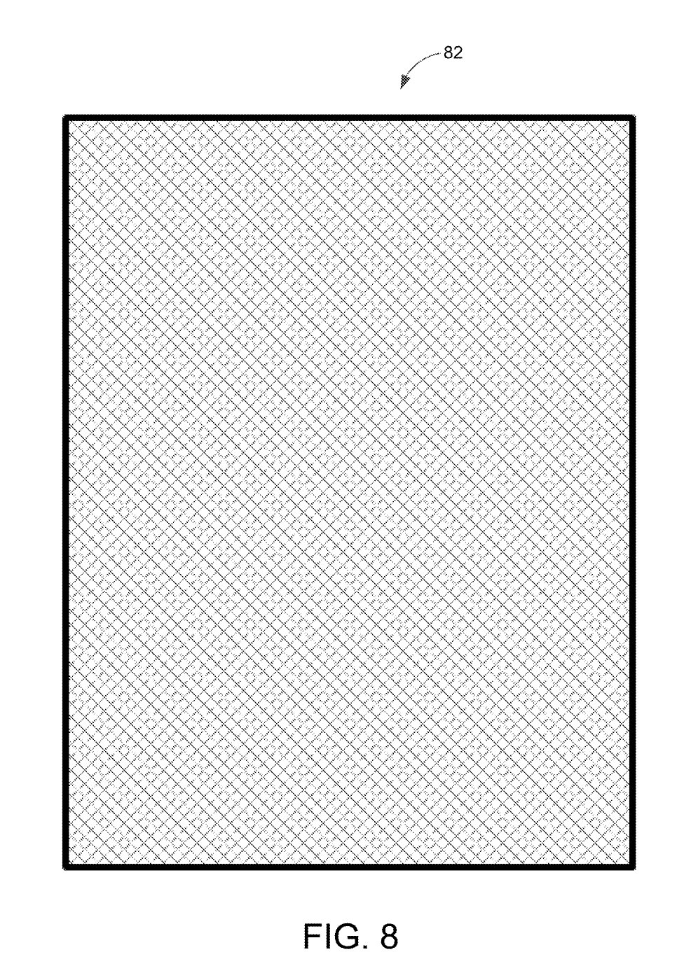

FIG. 8 illustrates one embodiment of a fiber weave 82 having a warp diagonal with respect to a direction of the conductive traces 46 of the circuit layer 42 shown in FIG. 5. Similarly, the fiber weave 82 has a warp diagonal to a direction of the conductive traces 66 of the circuit layer 62 shown in FIG. 6.

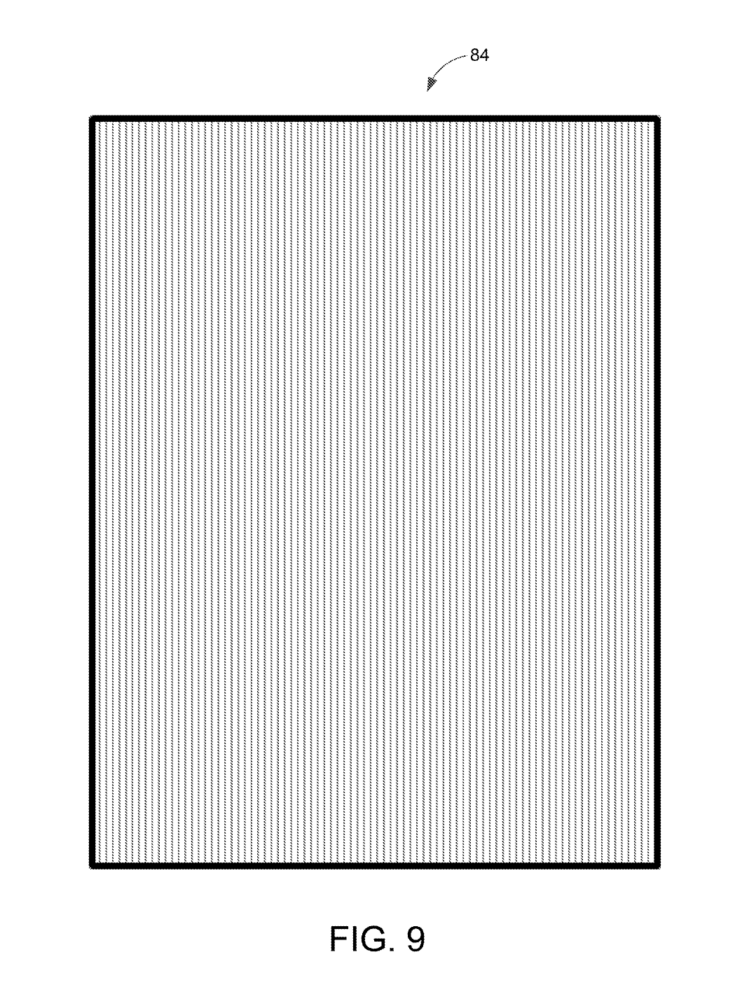

FIG. 9 illustrates one embodiment of a fiber weave 84 having a warp perpendicular with respect to a direction of the conductive traces 46 of the circuit layer 42 shown in FIG. 5. Similarly, the fiber weave 84 has a warp perpendicular to a direction of the conductive traces 66 of the circuit layer 62 shown in FIG. 6.

In some embodiments, the fiber weave, or reinforcement material, comprises a random direction with respect to the polyimide pre-impregnated material and/or the conductive traces 46 of the circuit layer 42 shown in FIG. 5 or the conductive traces 66 of the circuit layer 62 shown in FIG. 6. Those skilled in the art will recognize that the warp of the first and second reinforced pre-impregnated layers 50a, 50b, 66a, 66b illustrated in FIGS. 5 and 6 may be oriented any suitable direction.

In various embodiments, multiple high-temperature printed circuits, such as, for example, the multi-layer stack high-temperature printed circuits illustrated in FIGS. 5 and 6, may be stacked to form a multi-layer substrate capable of being formed in select areas during installation and use that can withstand elevated temperatures for an extended period of time. The multiple high-temperature printed circuits may comprise a variety of materials and/or weaves suitable for use in environments of up to at least about 260° C.

Although various embodiments have been described herein, many modifications, variations, substitutions, changes, and equivalents to those embodiments may be implemented and will occur to those skilled in the art. Also, where materials are disclosed for certain components, other materials may be used. It is therefore to be understood that the foregoing description and the appended claims are intended to cover all such modifications and variations as falling within the scope of the disclosed embodiments. The following claims are intended to cover all such modification and variations.

Various aspects of the subject matter described herein are set out in the following numbered clauses:

1. A high temperature printed circuit board (PCB), comprising: a first reinforced pre-impregnated layer; a second reinforced pre-impregnated layer, the first reinforced pre-impregnated layer and the second reinforced pre-impregnated layer comprising a plurality of glass fibers having a warp and a weft and impregnated with a polyimide high-temperature resin adhesive; a flexible metal-clad polyimide laminate material located between the first reinforced pre-impregnated layer and the reinforced second pre-impregnated layer, wherein the flexible metal-clad polyimide laminate material comprises a plurality of conductive traces; and a polyimide film disposed over the first pre-impregnated layer and the second pre-impregnated layer.

2. The high temperature PCB of clause 1, wherein the flexible metal-clad polyimide laminate material comprises a non-reinforced flexible polyimide laminate.

3. The high-temperature PCB of clause 2, wherein the flexible metal-clad polyimide laminate material comprises a non-reinforced adhesiveless flexible metal-clad polyimide laminate.

4. The high temperature PCB of clause 1, wherein the flexible metal-clad polyimide laminate material comprises a composite material having a polyimide component.

5. The high temperature PCB of clause 1, wherein the polyimide high-temperature resin adhesive comprises a high temperature thermoset polymer.

6. The high temperature PCB of clause 5, wherein the first and second reinforced pre-impregnated layers are configured to withstand temperatures of about 260° C.

7. The high temperature PCB of clause 6, wherein the first and second pre-impregnated layers comprise a composite material having a polyimide component.

8. The high temperature PCB of clause 1, wherein the polyimide film comprises a non-reinforced polyimide film.

9. The high temperature PCB of clause 1, wherein the fiber weave comprise a material selected from the group consisting of: glass, carbon, aramid, quartz and any other suitable material.

10. The high temperature PCB of clause 1, wherein the warp of the first and second reinforced pre-impregnated layers are parallel to a direction of the plurality of conductive traces of the flexible metal-clad polyimide laminate material.

11. The high temperature PCB of clause 1, wherein the warp of the first and second reinforced pre-impregnated layers are perpendicular to a direction of the conductive traces of the flexible metal-clad polyimide laminate material.

12. The high temperature PCB of clause 1, wherein the warp of the first and second reinforced pre-impregnated layers are diagonal with respect to a direction of the conductive traces of the flexible metal-clad polyimide laminate material.

13. The apparatus of clause 1, wherein the warp of the first and second reinforced pre-impregnated layers comprise a random direction with respect to a direction of the conductive traces of the non-reinforced adhesiveless flexible metal-clad polyimide laminate material.

14. A high temperature printed circuit board (PCB) comprising: a first reinforced pre-impregnated layer; a second reinforced pre-impregnated layer, the first reinforced pre-impregnated layer and the second reinforced pre-impregnated layer comprising a plurality of glass fibers having a warp and a weft and impregnated with a polyimide high-temperature resin adhesive; a flexible metal-clad polyimide laminate material located between the first reinforced pre-impregnated layer and the second reinforced pre-impregnated layer, wherein the non-reinforced adhesiveless flexible metal-clad polyimide laminate material comprises a plurality of conductive traces, wherein a first edge and a second edge of the first non-reinforced adhesiveless flexible metal-clad polyimide laminate material parallel to the conductive traces define a first slot and a second slot; and a polyimide film disposed over the first pre-impregnated layer and the second pre-impregnated layer.

15. The apparatus of clause 14, wherein the flexible metal-clad polyimide laminate material comprises a non-reinforced adhesiveless flexible metal-clad polyimide laminate material.

16. The apparatus of clause 14, wherein the polyimide high-temperature resin adhesive comprises a high-temperature thermoset polymer.

17. The apparatus of clause 14, wherein the polyimide high-temperature resin adhesive is configured to withstand temperatures of at least about 260° C.

18. The apparatus of clause 14, wherein the first and second pre-impregnated layers comprise a composite material having a polyimide component.

19. The apparatus of clause 14, wherein the laminate material comprises a composite material having a polyimide component.

20. A high temperature flexible printed circuit board (PCB) comprising: a first reinforced pre-impregnated layer; a second reinforced pre-impregnated layer, the first reinforced pre-impregnated layer and the second reinforced pre-impregnated layer comprising a plurality of glass fibers having a warp and a weft and impregnated with a polyimide high-temperature resin adhesive; a flexible metal-clad liquid crystal polymer laminate located between the first reinforced pre-impregnated layer and the reinforced second pre-impregnated layer, wherein the flexible metal-clad liquid crystal polymer laminate comprises a plurality of conductive traces; and a polyimide film disposed over the first pre-impregnated layer and the second pre-impregnated layer.

1. A high temperature printed circuit board (PCB), comprising:
a first reinforced pre-impregnated layer;
a second reinforced pre-impregnated layer, the first reinforced pre-impregnated layer and the second reinforced pre-impregnated layer comprising a plurality of glass fibers having a warp and a weft and impregnated with a polyimide high-temperature resin adhesive;
a flexible metal-clad polyimide laminate material located between the first reinforced pre-impregnated layer and the reinforced second pre-impregnated layer, wherein the flexible metal-clad polyimide laminate material comprises a plurality of conductive traces; and
a polyimide film disposed over the first pre-impregnated layer and the second pre-impregnated layer.

2. The high temperature PCB of claim 1, wherein the flexible metal-clad polyimide laminate material comprises a non-reinforced flexible polyimide laminate.

3. The high-temperature PCB of claim 2, wherein the flexible metal-clad polyimide laminate material comprises a non-reinforced adhesiveless flexible metal-clad polyimide laminate.

4. The high temperature PCB of claim 1, wherein the flexible metal-clad polyimide laminate material comprises a composite material having a polyimide component.

5. The high temperature PCB of claim 1, wherein the polyimide high-temperature resin adhesive comprises a high temperature thermoset polymer.

6. The high temperature PCB of claim 1, wherein the first and second reinforced pre-impregnated layers are configured to withstand temperatures of about 260° C.

7. The high temperature PCB of claim 6, wherein the first and second pre-impregnated layers comprise a composite material having a polyimide component.

8. The high temperature PCB of claim 1, wherein the polyimide film comprises a non-reinforced polyimide film.

9. The high temperature PCB of claim 1, wherein the glass fibers comprise a material selected from the group consisting of: glass, carbon, aramid, or quartz.

10. The high temperature PCB of claim 1, wherein the warp of the first and second reinforced pre-impregnated layers are parallel to a direction of the plurality of conductive traces of the flexible metal-clad polyimide laminate material.

11. The high temperature PCB of claim 1, wherein the warp of the first and second reinforced pre-impregnated layers are perpendicular to a direction of the conductive traces of the flexible metal-clad polyimide laminate material.

12. The high temperature PCB of claim 1, wherein the warp of the first and second reinforced pre-impregnated layers are diagonal with respect to a direction of the conductive traces of the flexible metal-clad polyimide laminate material.

13. The apparatus of claim 1, wherein the warp of the first and second reinforced pre-impregnated layers comprise a random direction with respect to a direction of the conductive traces of the non-reinforced adhesiveless flexible metal-clad polyimide laminate material.

14. A high temperature printed circuit board (PCB) comprising:
a first reinforced pre-impregnated layer;
a second reinforced pre-impregnated layer, the first reinforced pre-impregnated layer and the second reinforced pre-impregnated layer comprising a plurality of glass fibers having a warp and a weft and impregnated with a polyimide high-temperature resin adhesive;
a flexible metal-clad polyimide laminate material located between the first reinforced pre-impregnated layer and the second reinforced pre-impregnated layer, wherein the non-reinforced adhesiveless flexible metal-clad polyimide laminate material comprises a plurality of conductive traces, wherein a first edge and a second edge of the first non-reinforced adhesiveless flexible metal-clad polyimide laminate material parallel to the conductive traces define a first slot and a second slot; and
a polyimide film disposed over the first pre-impregnated layer and the second pre-impregnated layer.

15. The apparatus of claim 14, wherein the flexible metal-clad polyimide laminate material comprises a non-reinforced adhesiveless flexible metal-clad polyimide laminate material.

16. The apparatus of claim 14, wherein the polyimide high-temperature resin adhesive comprises a high-temperature thermoset polymer.

17. The apparatus of claim 16, wherein the first and second reinforced preimpregnated layers are configured to withstand temperatures of at least about 260° C.

18. The apparatus of claim 17, wherein the first and second pre-impregnated layers comprise a composite material having a polyimide component.

19. The apparatus of claim 14, wherein the laminate material comprises a composite material having a polyimide component.

20. A high temperature flexible printed circuit board (PCB) comprising:
a first reinforced pre-impregnated layer;
a second reinforced pre-impregnated layer, the first reinforced pre-impregnated layer and the second reinforced pre-impregnated layer comprising a plurality of glass fibers having a warp and a weft and impregnated with a polyimide high-temperature resin adhesive;
a flexible metal-clad liquid crystal polymer laminate located between the first reinforced pre-impregnated layer and the reinforced second pre-impregnated layer, wherein the flexible metal-clad liquid crystal polymer laminate comprises a plurality of conductive traces; and
a polyimide film disposed over the first pre-impregnated layer and the second pre-impregnated layer.
